(19) United States
(12) Patent Application Publication
(10) Pub. No.: US 2026/0093891 A1
(43) Pub. Date: Apr. 2, 2026

(54) ESTIMATING NOISE IMPACT ON DELAY AFTER A MODIFICATION TO AN INTEGRATED CIRCUIT DESIGN

(71) Applicant: INTERNATIONAL BUSINESS MACHINES CORPORATION, ARMONK, NY (US)

(72) Inventors: Jason David Morsey, Hopewell Junction, NY (US); Steven Eugene Washburn, Poughquag, NY (US); Alexander Joel Suess, Hopewell Junction, NY (US); Gregory Schaeffer, Poughkeepsie, NY (US)

(21) Appl. No.: 18/900,588

(22) Filed: Sep. 27, 2024

(51) Int. Cl. G06F 30/398; G06F 30/3312; H03K 5/1252

(52) U.S. Cl. CPC G06F 30/398; G06F 30/3312; H03K 5/1252

(57) ABSTRACT

A computer-implemented method for estimating noise adjustments in an integrated circuit design includes computing a first noise impact on timing calculation including a first slew rate and a first delay due to coupled noise prior to a physical design change; computing a second slew rate after the physical design change; and computing a second noise impact on a timing calculation based on the first delay and a ratio of the second slew rate and the first slew rate.

### BACKGROUND

### Technical Field

The present disclosure generally relates to design of integrated circuits (ICs), and more particularly to noise impact on timing of integrated circuits.

### Description of the Related Art

In the field of integrated circuits, a “net” refers to a connection between two or more pins. In very-large scale integration (VLSI) circuits, nets are sufficiently close to each other that capacitance becomes large enough to couple significant energy from one net to another net.

As a consequence of this capacitive coupling, energy is transferred from one net to another net by coupled electric/magnetic fields. Such coupled noise, in turn, can disrupt signal flow and have an impact on timing.

During design of a VLSI circuit, delays caused by coupled noise are computed. If the delays cause timing violations, design modifications are made until timing constraints are met.

### SUMMARY

According to various embodiments, a computer-implemented method for estimating noise adjustments in an integrated circuit design includes computing a first noise impact on timing calculation including a first slew rate and a first delay due to coupled noise prior to a physical design change; computing a second slew rate after the physical design change; and computing a second noise impact on timing calculation based on the first delay and a ratio of the second slew rate and the first slew rate.

In some embodiments, the second noise impact on timing calculation includes a second delay that is computed as a product of the ratio and the first delay.

In some embodiments, the physical design change includes resizing a first gate having an output pin electrically connected to an input pin of a second gate. The second noise impact on timing calculation includes a second delay. The first and second delays and the first and second slew rates are computed for the input of the second gate.

In some embodiments, the physical design change is for a first gate having an output pin electrically connected to an input pin of a second gate. A third gate is inserted between the first and second gates. The second noise impact on timing calculation includes a second delay. The first and second delays and the first and second slew rates are computed for the input of the second gate.

In some embodiments, the first delay is distributed between the input of the second gate and an input of the third gate. The second delay at the input of the second gate is a function of the ratio and the distributed delay at the second gate. A slew rate is computed for the input of the third gate, and a delay for the input of the third gate is computed as a function of the distributed delay and a ratio of the slew rate for the input of the third gate and the slew rate for the input of the second gate.

In some embodiments, a first wire is connected between an output pin of the third gate and an input pin of the second gate, and a second wire is connected between an output pin of the first gate and an input pin of the third gate. The first delay is distributed as a function of relative lengths of the first and second wires.

According to various embodiments, a computer includes a memory having computer readable instructions, and a processor set for executing the computer readable instructions to configure the computer to estimate delay after modification of an integrated circuit (IC) design. The delay after modification is estimated as a function of delay prior to the modification and a ratio of slew rate after the modification and slew rate prior to the modification.

In some embodiments, the delay for an input of a gate is estimated as

$${N}_{2} = \frac{{S}_{2}}{{S}_{1}} {N}_{1} .$$

where S₁ is slew rate for the input of the gate prior to the modification, S₂ is slew rate for the input of the gate after the modification, N₁ is delay for the gate prior to the modification, and N₂ is estimated delay after the modification.

In some embodiments, the gate is a second gate, and a first gate has an output electrically connected to an input of the second gate. The modification includes resizing the first gate. N₁ and S₁ are computed for the input of the second gate before the first gate is resized, and S₂ is computed and N₂ is estimated for the input of the second gate after the first gate has been resized.

In some embodiments, the gate is a second gate. Prior to the modification, the circuit includes a first gate having an output electrically connected to an input of the second gate. The modification includes inserting a third gate between the first and second gates. N₁ and S₁ are computed for the input of the second gate before the gate insertion, and S₂ is computed and N₂ is estimated for the input of the second gate after the gate insertion.

In some embodiments, N₁/2 is used instead of N₁ for the estimate of delay for the input of the second gate. Slew rate is computed for an input of the third gate, and an estimated delay for the input of the third gate is computed as a product of N₁/2 and a ratio of S₁ and the slew rate computed for the input of the third gate.

In some embodiments, the executable instructions further configure the computer to make a plurality of incremental modifications to the IC design and corresponding estimated delays. Immediately after each incremental modification has been made, the corresponding estimated delay is used to check for timing violations.

According to various embodiments, a computer program product includes one or more computer-readable memory devices encoded with data including computer-readable instructions that, when executed, causes a processor set to estimate timing delay for a gate after a modification to an integrated circuit design. The timing delay is estimated as a function of delay for the gate prior to the modification and a ratio of slew rate for the gate after the modification and slew rate for the gate prior to the modification.

In some embodiments, the timing delay is estimated as

$${N}_{2} = \frac{{S}_{2}}{{S}_{1}} {N}_{1} .$$

where S₁ is slew rate for an input of the gate prior to the modification, S₂ is slew rate for the input of the gate after the modification, N₁ is timing delay for the input of the gate prior to the modification, and N₂ is estimated timing delay after the modification.

In some embodiments, the gate is a second gate, and a first gate has an output electrically coupled to the input of the second gate. The modification includes resizing the first gate. N₁ and S₁ are computed for the input of the second gate prior to the modification, S₂ is computed for the input of the second gate after the modification, and N₂ is estimated for the input of the second gate after the modification.

In some embodiments, the gate is a second gate. Prior to the modification, the circuit includes a first gate having an output electrically connected to the input of the second gate. The modification includes inserting a third gate between the first and second gates. N₁ and S₁ are computed for the input of the second gate prior to the modification, S₂ is computed for the input of the second gate after the modification, and N₂ is estimated for the input of the second gate after the modification.

In some embodiments, a plurality of additional modifications are made to the integrated circuit design, and a timing delay is estimated after each additional modification has been made. Immediately after a given timing delay has been estimated, the given timing delay is used to check for one or more timing violations.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1 is a method of estimating delay at a gate of an integrated circuit (IC), consistent with an illustrative embodiment.

FIG. 2 is an illustration of two gates and a net before and after an incremental design modification, consistent with an illustrative embodiment.

FIG. 3 is an illustration of two gates and a net before an incremental design modification, and three gates and two nets after the design modification, consistent with an illustrative embodiment.

FIG. 4 is an IC design method, consistent with an illustrative embodiment.

FIG. 5 is a computing environment for IC design, consistent with an illustrative embodiment.

### DETAILED DESCRIPTION

### Example Method

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, in order to avoid unnecessarily obscuring aspects of the present teachings.

The present disclosure generally relates to delay in an IC design after the design has been modified. By virtue of the concepts discussed herein, the delay is estimated with little loss in accuracy. Estimation of the delay is much faster and far less computationally intensive than simulation. The delay estimation also enables incremental design modifications to be made efficiently.

Consider the example of first and second gates in the design. A wire connects an output pin of the first gate to an input pin of the second gate. When the output pin of the first gate changes from a first voltage level to a higher second voltage level, it will take time for the input pin of the second gate to see the second voltage level. The time to transition from one voltage level to another voltage level is referred to as “slew rate.” The slew rate is quantified as a measure of this transition time.

That wire (net) is capacitively coupled with other wires (nets) in the design. As a result, a signal traveling along the wire from the output of the first gate to the input of the second gate will be impacted by coupled noise. That coupled noise, in turn, will disrupt the signal and cause a timing delay. This delay is quantified as a measure of time. It works as an adjustment or penalty to the signal.

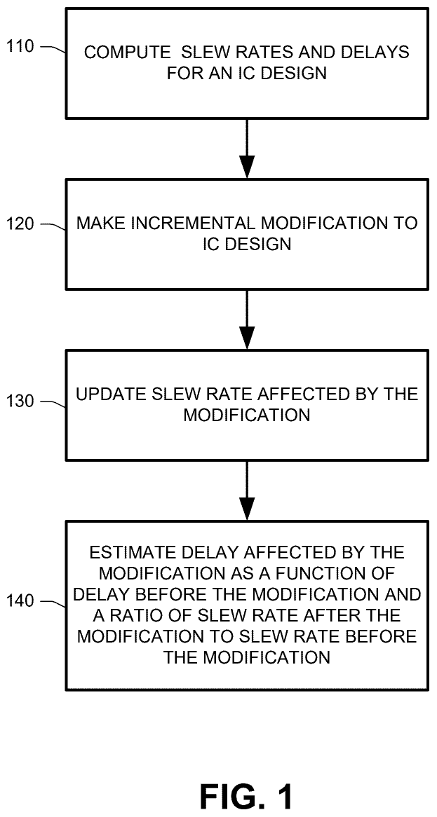

Reference is made to FIG. 1, which illustrates a method of estimating delay due to coupled noise at a gate in an IC design after the design has been modified. At block 110, the method begins with pre-computed values of slew rate (S₁) and delay due to coupled noise (D₁) at a gate prior to a design modification. The subscript “1” refers to the slew rate and delay prior to the design modification, and the subscript “2” will refer to the slew rate and delay after the design modification. Slew rates and delays for the IC design may have previously been computed, for example, by running a field solver, accessing capacitive coupling values in the IC design, focusing on a circuit with the net and neighboring nets, and running a simulator to solve the circuit. This approach is iterative and computationally intensive.

At block 120, an incremental modification to the IC design is made. Examples of the modification include resizing the first gate, inserting a third gate between the first and second gates, and rerouting the net.

At block 130, the slew rate (S₂) affected by the modification is updated. For example, a timing analysis may be performed. The timing analysis is not computationally intensive and does not require a simulation.

At block 140, the delay due to coupled noise (D₂) affected by the modification is estimated. The estimate is based on the assumption that the coupled noise after the modification is the same as before the modification. As the transition from one voltage level to the other voltage level becomes faster, whereby the signal on the wire is less susceptible to coupled noise, which should reduce the delay. It has been found that the ratio D₂/D₁ is about equal to the ratio S₂/S₁. Instead of performing a computationally-intensive simulation to find the delay (D₂), an accurate estimate may be computed as

$${D}_{2} = \frac{{S}_{2}}{{S}_{1}} {D}_{1} .$$

More generally, the delay (D₂) after the modification may be computed as a function of the delay (D₁) before the modification and the ratio of the slew rate (S₂) after the modification to the slew rate (S₁) before the modification. Thus, the delay (D₂) after modification is computed algebraically instead of performing a full simulation or other computationally intensive method.

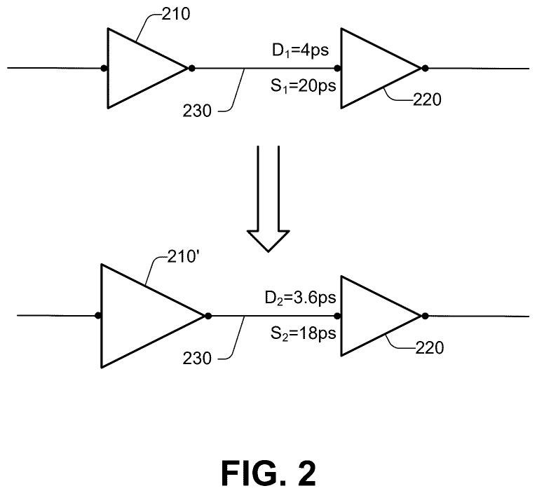

Reference is made to FIG. 2, which illustrates a first gate 210 and a second gate 220 and a wire 230 connecting an output pin of the first gate 210 to an input pin of the second gate 220. The input pin of the second gate 220 “sees” a slew rate of S₁=20 picoseconds and a delay of D₁=4 picoseconds.

A modification is made by replacing the first gate 210 with a larger first gate 210′. With this resizing, the slew rate at the input pin of the second gate 220 is reduced to S₂=18 picoseconds. The delay at the input of the second gate 220 is estimated as

$${D}_{2} = \frac{18}{20} 4 = 3.6 picoseconds .$$

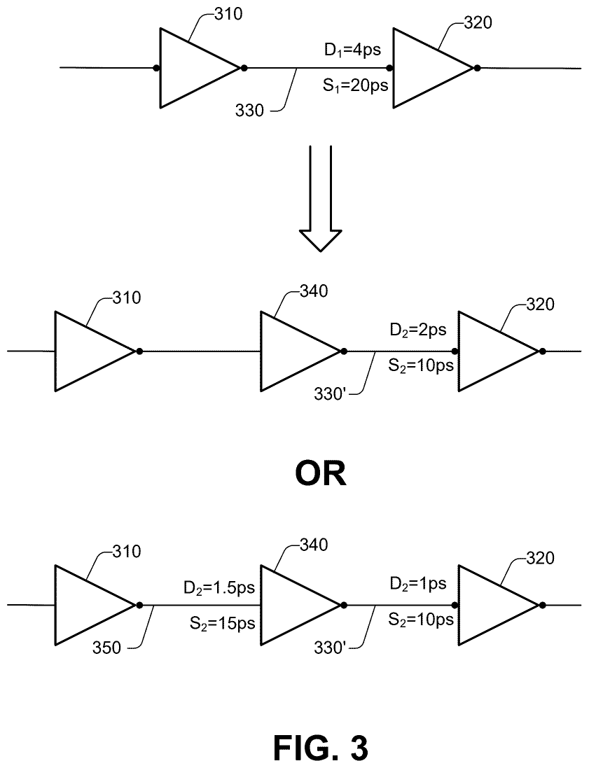

Reference is made to FIG. 3, which illustrates a first gate 310 and a second gate 320 and a wire 330 connecting an output pin of the first gate 310 to an input pin of the second gate 320. The input pin of the second gate 320 “sees” a slew rate of S₁=20 picoseconds and a delay of D₁=4 picoseconds.

A modification is made by inserting a third gate 340 between the first gate 310 and the second gate 320. The wire 330′ is shortened and now connects an output pin of the third gate 340 to the input pin of the second gate 320. With this gate insertion, the slew rate at the input pin of the second gate 320 is reduced to S₂₌₁₀ picoseconds. The delay at the input of the second gate 320 is estimated as

$${D}_{2} = \frac{10}{20} 4 = 2 picoseconds .$$

In the alternative, the value for N₁ (4 picoseconds at the input pin of the second gate 320) is distributed among the input pins of the second and third gates 320 and 340. For example, the delay of D₁=4 picoseconds prior to the modification at the input of the second gate 320 is distributed equally, and the delay after modification is estimated as

$${D}_{2} = \frac{10}{20} 2 = 1 picosecond .$$

Slew rate at the input of the third gate 340 is computed as 15 picoseconds, and the delay at the input of the third gate is estimated as

$${D}_{2} = \frac{15}{20} 2 = 1.5 picoseconds .$$

If the third gate 340 is not centered between the first gate 310 and the second gate 320, the distribution of the 4 picosecond delay may be proportional to the relative length of the wire 330′ and a wire 350 connecting to an input pin of the third gate 340. For example, if the wire 350 is three times longer than the wire 330′, the distributed delay at the input of the second gate 320 may be one quarter of the 4 picosecond delay, and the delay at the input of the third gate 340 may be three quarters of the 4 picosecond delay. As a result, delay at the input of the second gate 320 is estimated as

$${D}_{2} = \frac{10}{20} 1 = 0.5 picoseconds ,$$

and delay at the input of the third gate 340 is estimated as

$${D}_{2} = \frac{15}{20} 3 = 2 \text{.25} picoseconds .$$

In addition to greatly increasing the speed and reducing the computation burden of determining the delay after an incremental update, a method herein can make it faster and more efficient to update the design of a VLSI circuit.

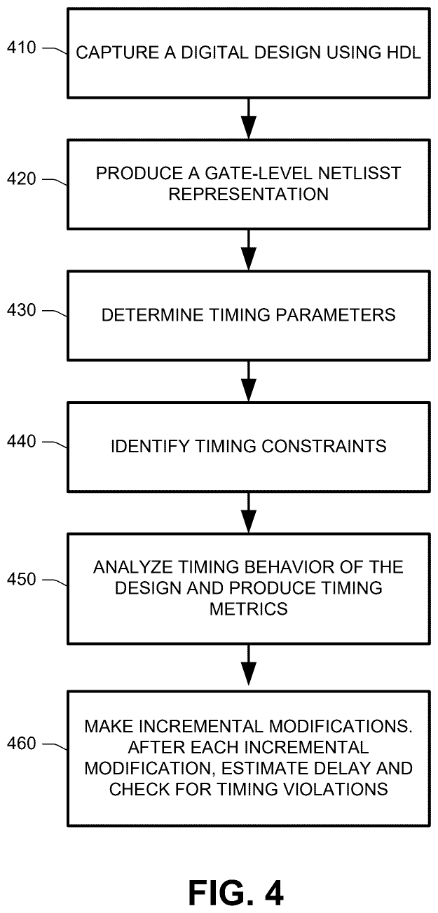

Reference is made to FIG. 4. Consider the following acts performed during design of a VLSI circuit. At block 410, a digital design of the circuit is captured using a Hardware Description Language. The design includes the logical functionality, interconnections, and timing constraints of the circuit.

At block 420, the digital design undergoes synthesis to produce a gate-level netlist representation. The netlist represents the design in terms of logic gates and their interconnections. The netlist also includes information about gate delays, library cells, and other design-specific details.

At block 430, standard cells in the design are characterized to determine their timing parameters. This characterization involves measuring the timing characteristics of the cells, such as propagation delay, rise/fall times, input/output capacitances, and other electrical properties. Typically, this information is provided by the cell library vendor.

At block 440, timing constraints are identified. The timing constraints define the desired timing behavior of the design.

At block 450, static timing analysis is performed. The netlist, library characterization data, and timing constraints are fed to a static analysis tool, which analyzes the timing behavior of the design and computes various timing metrics.

At block 460, incremental design modifications are performed. Modifications to the design may include restructuring logic, adjusting clock trees, resizing gates to meet timing constraints, etc. After each incremental design modification, a new slew rate is determined, the delay is estimated, and timing violations are checked. If a violation occurs, the incremental modification is discarded, and another incremental change is attempted. This is much faster and far less computationally intensive than making a set of changes to a design and then re-evaluating the modified design, only to find out that certain changes have to be undone because they resulted in timing violations.

### Example Computing Environment

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

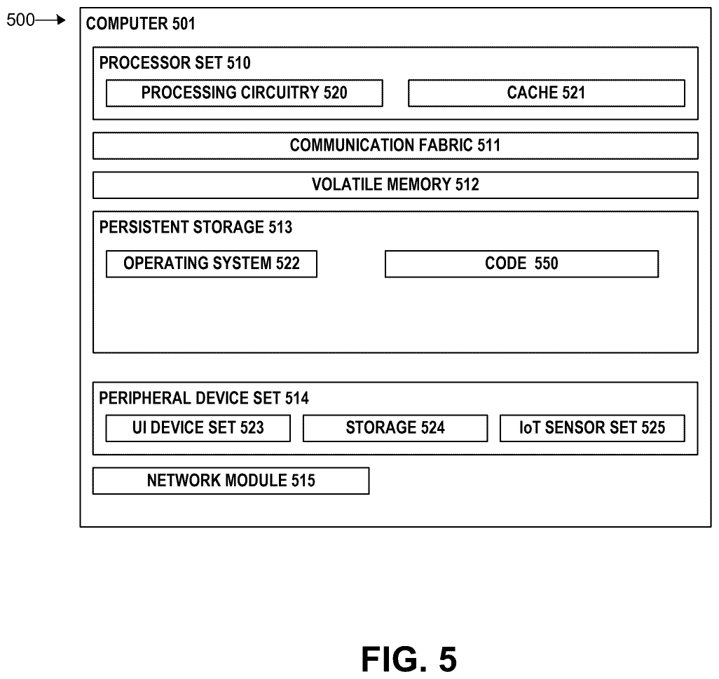

Reference is made to FIG. 5. Computing environment 500 contains an example of an environment for the execution of at least some computer code 550 involved in performing the inventive methods, which includes estimating noise impact on delay after each incremental design change. In addition to the computer code 550, computing environment 500 includes, for example, computer 501. In this embodiment, computer 501 includes processor set 510 (including processing circuitry 520 and cache 521), communication fabric 511, volatile memory 512, persistent storage 513 (including operating system 522 and computer code 550, as identified above), peripheral device set 514 (including user interface (UI) device set 523, storage 524, and Internet of Things (IoT) sensor set 525), and network module 515.

COMPUTER 501 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as a remote database. As is well understood in the art of computer technology, and depending upon the technology, performance of a computer-implemented method may be distributed among multiple computers and/or between multiple locations. On the other hand, in this presentation of computing environment 500, detailed discussion is focused on a single computer, specifically computer 501, to keep the presentation as simple as possible. Computer 501 may be located in a cloud, even though it is not shown in a cloud in FIG. 5. On the other hand, computer 501 is not required to be in a cloud except to any extent as may be affirmatively indicated.

PROCESSOR SET 510 includes one, or more, computer processors of any type now known or to be developed in the future. Processing circuitry 520 may be distributed over multiple packages, for example, multiple, coordinated integrated circuit chips. Processing circuitry 520 may implement multiple processor threads and/or multiple processor cores. Cache 521 is memory that is located in the processor chip package(s) and is typically used for data or code that should be available for rapid access by the threads or cores running on processor set 510. Cache memories are typically organized into multiple levels depending upon relative proximity to the processing circuitry. Alternatively, some, or all, of the cache for the processor set may be located “off chip.” In some computing environments, processor set 510 may be designed for working with qubits and performing quantum computing.

Computer readable program instructions are typically loaded onto computer 501 to cause a series of operational steps to be performed by processor set 510 of computer 501 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 521 and the other storage media discussed below. The program instructions, and associated data, are accessed by processor set 510 to control and direct performance of the inventive methods. In computing environment 500, at least some of the instructions for performing the inventive methods may be stored in the computer code 550 in persistent storage 513.

COMMUNICATION FABRIC 511 is the signal conduction path that allows the various components of computer 501 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 512 is any type of volatile memory now known or to be developed in the future. Examples include dynamic type random access memory (RAM) or static type RAM. Typically, volatile memory 512 is characterized by random access, but this is not required unless affirmatively indicated. In computer 501, the volatile memory 512 is located in a single package and is internal to computer 501, but, alternatively or additionally, the volatile memory may be distributed over multiple packages and/or located externally with respect to computer 501.

PERSISTENT STORAGE 513 is any form of non-volatile storage for computers that is now known or to be developed in the future. The non-volatility of this storage means that the stored data is maintained regardless of whether power is being supplied to computer 501 and/or directly to persistent storage 513. Persistent storage 513 may be a read only memory (ROM), but typically at least a portion of the persistent storage allows writing of data, deletion of data and re-writing of data. Some familiar forms of persistent storage include magnetic disks and solid state storage devices. Operating system 522 may take several forms, such as various known proprietary operating systems or open source Portable Operating System Interface-type operating systems that employ a kernel. The computer code 550 typically includes at least some of the computer code involved in performing the inventive methods.

PERIPHERAL DEVICE SET 514 includes the set of peripheral devices of computer 101. Data communication connections between the peripheral devices and the other components of computer 501 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 523 may include components such as a display screen, speaker, microphone, wearable devices (such as goggles and smart watches), keyboard, mouse, printer, touchpad, game controllers, and haptic devices. Storage 524 is external storage, such as an external hard drive, or insertable storage, such as an SD card. Storage 524 may be persistent and/or volatile. In some embodiments, storage 524 may take the form of a quantum computing storage device for storing data in the form of qubits. In embodiments where computer 501 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 525 is made up of sensors that can be used in Internet of Things applications. For example, one sensor may be a thermometer and another sensor may be a motion detector.

NETWORK MODULE 515 is the collection of computer software, hardware, and firmware that allows computer 101 to communicate with other computers through a WAN. Network module 515 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 515 are performed on the same physical hardware device. In other embodiments (for example, embodiments that utilize software-defined networking (SDN)), the control functions and the forwarding functions of network module 515 are performed on physically separate devices, such that the control functions manage several different network hardware devices. Computer readable program instructions for performing the inventive methods can typically be downloaded to computer 501 from an external computer or external storage device through a network adapter card or network interface included in network module 515.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A computer-implemented method for estimating noise adjustments in an integrated circuit (IC) design, the computer-implemented method comprising:
computing a first noise impact on timing calculation including a first slew rate and a first delay due to coupled noise prior to a physical design change;
computing a second slew rate after the physical design change; and
computing a second noise impact on timing calculation based on the first delay and a ratio of the second slew rate and the first slew rate.

2. The method of claim 1, wherein:
the second noise impact on timing calculation includes a second delay that is computed as a product of the ratio and the first delay.

3. The method of claim 1, wherein:
the physical design change comprises resizing a first gate having an output pin electrically connected to an input pin of a second gate;
the second noise impact on timing calculation includes a second delay; and
the first and second delays and the first and second slew rates are computed for the input of the second gate.

4. The method of claim 1, wherein:
the physical design change is for a first gate having an output pin electrically connected to an input pin of a second gate;
a third gate is inserted between the first and second gates;
the second noise impact on timing calculation includes a second delay; and
the first and second delays and the first and second slew rates are computed for the input of the second gate.

5. The method of claim 4, wherein:
the first delay is distributed between the input pin of the second gate and an input pin of the third gate;
the second delay at the input pin of the second gate is a function of the ratio and distributed delay at the second gate;
a slew rate is computed for the input pin of the third gate; and
a delay for the input pin of the third gate is computed as a function of the distributed delay and a ratio of the slew rate for the input of the third gate and the slew rate for the input of the second gate.

6. The method of claim 5, wherein:
a first wire is connected between an output pin of the third gate and the input pin of the second gate;
a second wire is connected between an output pin of the first gate and the input pin of the third gate; and
the first delay is distributed as a function of relative lengths of the first and second wires.

7. The method of claim 1, wherein:
the second noise impact on timing calculation includes a second delay; and
the second delay is computed and used immediately after the physical design change to check for timing violations.

8. A computer comprising:
a memory having computer readable instructions; and
a processor set for executing the computer readable instructions to configure the computer to estimate delay after modification of an integrated circuit (IC) design;
wherein the delay after modification is estimated as a function of a delay prior to the modification and a ratio of a slew rate after the modification and a slew rate prior to the modification.

9. The computer of claim 8, wherein the delay for an input of a gate is estimated as
$${N}_{2} = \frac{{S}_{2}}{{S}_{1}}$$
where S₁ is a slew rate for the input of the gate prior to the modification, S₂ is a slew rate for the input of the gate after the modification, N₁ is delay for the gate prior to the modification, and N₂ is an estimated delay after the modification.

10. The computer of claim 9, wherein
the gate is a second gate;
the modification comprises resizing a first gate having an output electrically connected to an input of the second gate;
N₁ and S₁ are computed for the input of the second gate before the first gate is resized; and
S₂ is computed and N₂ is estimated for the input of the second gate after the first gate has been resized.

11. The computer of claim 9, wherein:
the gate is a second gate;
prior to the modification, the circuit includes a first gate having an output electrically connected to an input of the second gate;
the modification comprises inserting a third gate between the first and second gates;
N₁ and S₁ are computed for the input of the second gate before the gate insertion; and
S₂ is computed and N₂ is estimated for the input of the second gate after the gate insertion.

12. The computer of claim 11, wherein:
N₁/2 is used instead of N₁ for the estimate of delay for the input of the second gate;
a slew rate is computed for an input of the third gate; and
an estimated delay for the input of the third gate is computed as a product of N₁/2 and a ratio of S₁ and the slew rate computed for the input of the third gate.

13. The computer of claim 8, wherein the computer readable instructions further configure the computer to:
make a plurality of incremental modifications to the IC design and corresponding estimated delays; and
immediately after each incremental modification has been made, use the corresponding estimated delay to check for timing violations.

14. The computer of claim 8, wherein if an incremental modification causes a timing violation, said incremental modification is discarded and another incremental modification is attempted.

15. A computer program product comprising one or more computer-readable memory devices encoded with data including computer-readable instructions that, when executed, causes a processor set to estimate a timing delay for a gate after a modification to an integrated circuit design, wherein the timing delay is estimated as a function of timing delay for the gate prior to the modification and a ratio of slew rate for the gate after the modification and slew rate for the gate prior to the modification.

16. The computer program product of claim 15, wherein the timing delay is estimated as
$${N}_{2} = \frac{{S}_{2}}{{S}_{1}} {N}_{1} .$$
where S₁ is slew rate for an input of the gate prior to the modification, S₂ is slew rate for the input of the gate after the modification, N₁ is timing delay for the input of the gate prior to the modification, and N₂ is estimated timing delay after the modification.

17. The computer program product of claim 16, wherein:
the gate is a second gate;
a first gate has an output electrically coupled to the input of the second gate;
the modification comprises resizing the first gate;
N₁ and S₁ are computed for the input of the second gate prior to the modification;
S₂ is computed for the input of the second gate after the modification; and
N₂ is estimated for the input of the second gate after the modification.

18. The computer program product of claim 16, wherein:
the gate is a second gate;
prior to the modification, the circuit includes a first gate having an output electrically connected to the input of the second gate;
the modification comprises inserting a third gate between the first and second gates;
N₁ and S₁ are computed for the input of the second gate prior to the modification;
S₂ is computed for the input of the second gate after the modification; and
N₂ is estimated for the input of the second gate after the modification.

19. The computer program product of claim 15, wherein:
a plurality of additional modifications are made to the integrated circuit design;
a timing delay is estimated after each additional modification has been made; and
immediately after a given timing delay has been estimated, the given timing delay is used to check for one or more timing violations.

20. The computer program product of claim 15, wherein if the modification causes a timing violation, the modification is discarded and another modification is attempted:
